(19) United States
(12) Patent Application Publication
(10) Pub. No.: US 2010/0271482 A1
(43) Pub. Date: Oct. 28, 2010

(54) IMAGING ELEMENT UNIT

(75) Inventors: Motohiko OTSUKI, Miyagi-ken (JP); Hirofumi FURUSAWA, Miyagi-ken (JP)

Correspondence Address: Beyer Law Group LLP, P.O. BOX 1687, Cupertino, CA, 95015-1687, US

(73) Assignee: ALPS ELECTRIC CO., LTD., Tokyo (JP)

(21) Appl. No.: 12/753,058

(22) Filed: Apr. 1, 2010

(30) Foreign Application Priority Data
Apr. 23, 2009 (JP) 2009-104709

(51) Int. Cl. H04N 7/18; H01L 31/0232; H01L 31/09

(52) U.S. Cl. 348/148; 250/226; 348/E07.085

(57) ABSTRACT

An imaging element unit includes an imaging element configured to include an imaging surface having a plurality of R pixels, G pixels and B pixels, and an infrared cut filter configured to be placed in a position immediately in front of the imaging surface, wherein the transmittance characteristics of the infrared cut filter is determined so that an RGB combined relative sensitivity which is a combined value of unique sensitivities of the R pixels, the G pixels and the B pixels and a relative sensitivity of the imaging surface determined by the transmittance characteristics of the infrared cut filter show each of the following sensitivities with the respect to each of the following wavelengths longer than 600 nm.

| λ | |
|---|---|
| (wavelength: unit of nm) | relative sensitivity |
| 650 | 77 ± 10 |
| 700 | 62 ± 10 |
| 750 | 44 ± 7 |
| 800 | 26 ± 7 |
| 850 | 7 ± 5 |
| 900 | 5 ± 5 |

### CROSS REFERENCE TO RELATED APPLICATION

The present invention contains subject matter related to Japanese Patent Application JP 2009-104709 filed in the Japanese Patent Office on Apr. 23, 2009, the entire contents of which being incorporated herein by reference.

### BACKGROUND

1. Technical Field

The present invention relates to an imaging element unit provided with an imaging element and an infrared cut filter.

2. Related Art

An imaging element (CCD or CMOS) generally shows a high RGB combined relative sensitivity over a wide range of wavelengths of electromagnetic wave. Thereby, if visible light and infrared light are together incident on a camera module provided with the imaging element, the color reproducibility of an image taken by the imaging element is degraded.

For this reason, in a related art, the camera module is provided with an infrared cut filter which enables visible light of 400 to 600 nm in wavelength to transmit as much as nearly 100% and further cuts electromagnetic waves of roughly 650 nm in wavelength by as much as about 50%, thereby cutting most infrared light longer than 700 nm in wavelength.

Meanwhile, in order to clearly take an image of a subject in a dark environment such as nighttime when the amount of visible light is insufficient, the imaging is required to use infrared light. However, when the above-described infrared cut filter is provided, since the relative sensitivity of the image element is much lowered with respect to wavelengths longer than 600 nm, an image of a subject cannot be clearly taken in the dark environment although the imaging has been performed using infrared light.

Japanese Unexamined Utility Model Registration Application Publication No. 2-88851 is an example of a related art for solving this problem. The camera in the related art is provided with an infrared cut filter which is movable between a position immediately in front of an imaging surface of an imaging element and a position withdrawn from the position immediately in front of the imaging surface.

This camera solves the problem by placing the infrared cut filter in the position immediately in front of the imaging element in an environment such as daytime when the amount of visible light is sufficient, and by withdrawing the infrared cut filter from the position immediately in front of the imaging element in an environment such as nighttime when visible light is not sufficient.

### SUMMARY

Japanese Unexamined Utility Model Registration Application Publication No. 2-88851 needs a mechanism for moving the infrared cut filter and thus its manufacturing costs are high. Furthermore, it needs space for withdrawing the infrared cut filter and thus the camera module is subject to increases in size.

An advantage of some aspects of the invention is to provide an imaging element unit capable of clearly imaging a subject in an environment where the amount of visible light is not sufficient as well as an environment where visible light is sufficient, without causing complexity of the structure or high costs.

An RGB combined relative sensitivity (a unique relative sensitivity of the imaging element) of the imaging element cannot be changed after the imaging element is manufactured, but an actual relative sensitivity of the imaging element can be adjusted by covering an imaging surface with an infrared cut filter. The relative sensitivity of the imaging element with respect to an electromagnetic wave of 600 nm to 900 nm in wavelength is set in a predetermined range in consideration of the transmittance characteristics of the infrared cut filter, and thereby a degradation of color reproducibility can be maximumly suppressed at the time of imaging using visible light, and further a subject can be clearly imaged at the time of an imaging using infrared light.

An imaging element unit according to an aspect of the invention includes an imaging element configured to include an imaging surface having a plurality of R pixels, G pixels and B pixels, and an infrared cut filter configured to be placed in a position immediately in front of the imaging surface, wherein the transmittance characteristics of the infrared cut filter are determined so that an RGB combined relative sensitivity which is a combined value of unique sensitivities of the R pixels, the G pixels and the B pixels and a relative sensitivity of the imaging surface determined by the transmittance characteristics of the infrared cut filter show each of the following sensitivities with the respect to each of the following wavelengths longer than 600 nm.

| λ | |
|---|---|
| (wavelength: unit of nm) | relative sensitivity |
| 650 | 77 ± 10 |
| 700 | 62 ± 10 |
| 750 | 44 ± 7 |
| 800 | 26 ± 7 |
| 850 | 7 ± 5 |
| 900 | 5 ± 5 |

An imaging element unit according to another aspect of the invention includes an imaging element configured to include an imaging surface having a plurality of R pixels, G pixels and B pixels, and an infrared cut filter configured to be placed in a position immediately in front of the imaging surface, wherein the transmittance characteristics of the infrared cut filter is determined so that, in an RGB combined relative sensitivity which is a combined value of unique sensitivities of the R pixels, the G pixels and the B pixels and a relative sensitivity of the imaging surface determined by the transmittance characteristics of the infrared cut filter, the relative sensitivity with respect to each wavelength of 650 nm to 900 nm lies in an area surrounded by straight lines connecting the following P1 to the P2, the P2 to the P4, the P4 to the P6, the P6 to the P5, the P5 to the P3, and the P3 to the P1, respectively, when the wavelength of an electromagnetic wave is expressed on the transverse axis and the relative sensitivity with respect to each wavelength is expressed on the longitudinal axis.

A first relative sensitivity in a wavelength λ, of 650 nm P1: 87

A second relative sensitivity in a wavelength λ, of 650 nm P2: 67

A first relative sensitivity in a wavelength λ, of 850 nm P3: 12

A second relative sensitivity in a wavelength λ, of 850 nm P4: 2

A first relative sensitivity in a wavelength λ, of 900 nm P5: 10

A second relative sensitivity in a wavelength λ, of 900 nm P6: 0

Even an imaging element unit according to any of the aspects can be embedded in a car-mounted camera.

The infrared cut filter according to the aspects of the invention is not movable with respect to the imaging element but is placed immediately in front of the imaging element; however, it can clearly image a subject in an environment where the amount of visible light is not sufficient like nighttime as well as in an environment where the amount of visible light is sufficient like daytime. In addition, the infrared cut filter is not required to be moved with respect to the imaging element and thereby the structure is not complex and manufacturing costs are not high.

### BRIEF DESCRIPTION OF THE DRAWINGS

FIG. 1 is a longitudinal sectional view of a camera module according to an embodiment of the invention;

FIG. 2 is a spectral characteristic graph illustrating a correspondence relation between a wavelength of an electromagnetic wave and a relative sensitivity of an imaging element;

FIG. 3A is a spectral characteristic graph illustrating a unique RGB combined relative sensitivity of the imaging element with respect to other wavelengths in the embodiment 1, FIG. 3B is a spectral characteristic graph illustrating a transmittance of the infrared cut filter in the same embodiment, FIG. 3C is a spectral characteristic graph illustrating a relative sensitivity of the imaging element when the infrared cut filter is provided in the same embodiment, and FIG. 3D is a spectral characteristic graph which gathers the respective graphs 3A to 3C in one.

FIGS. 4A-D are spectral characteristic graphs the same as those shown in FIG. 3 according to an embodiment 2.

### DESCRIPTION OF EXEMPLARY EMBODIMENTS

Embodiments of the invention will now be described with reference to the accompanying drawings.

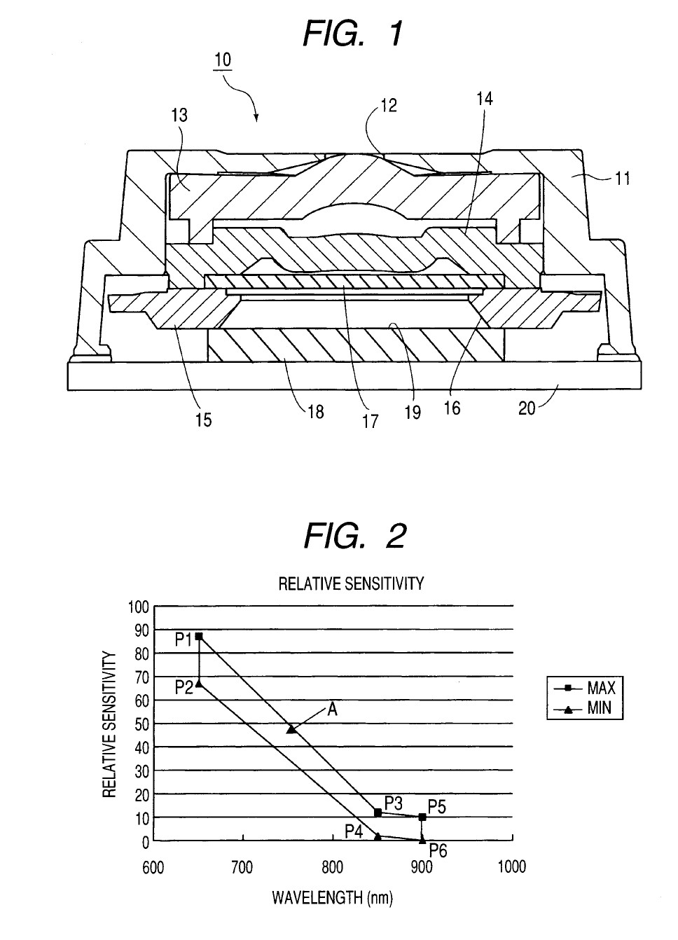

A camera module 10 has a configuration such as shown in FIG. 1, and can be used as a car-mounted camera (not shown) mounted in a vehicle, or as a fixed surveillance camera for use in buildings.

In a holder 11 which is a rotating body and the center of which is empty with respect to the axial line thereof, one end portion in the axial direction is entirely open, and the other end portion is formed with a lighting hole 12 of a small diameter in the middle thereof. Inside the holder 11, two lenses 13 and 14, and a spacer 15 including a center hole 16 in its center portion, are contained in the stacked manner in the axial direction of the holder 11, and an infrared cut filter (IRCF) 17 is fixedly interposed between the lens 14 and the spacer 15.

The infrared cut filter 17 is a lamination type (reflection type) and is formed by providing a thin film the transmittance of which with respect to infrared light is lower than that with respect to visible light, on one surface (either the front surface or the rear surface) of a filter substrate made of glass. Several tens of layers, each of which is several tens to several hundreds of nm thick, are deposited so as to overlap each other having different refractive indexes and thicknesses, to form this thin film. In addition, an anti-reflection coating, the reflectance of which is equal to or less than 1% with respect to an electromagnetic wave of 400 nm to 900 nm, is formed on another surface of the filter substrate of the infrared cut filter 17. A design method for giving the desired transmittance characteristics to the infrared cut filter 17, by properly selecting the number, thickness and refractive index of each layer of the thin film, has been known in the art.

A substrate 20 which supports an imaging element 18 (for example, a CCD or a CMOS) in a state of being electrically connected to the imaging element 18 is fixed to the one end portion of the holder 11. A cover glass (not shown) fixed to the surface of an imaging surface 19 of the imaging element 18 makes contact to a face opposite to the lens 14 in the spacer 15. The imaging surface 19 has a plurality of pixels covered with primary color filters of several colors such as G (green), B (blue) and R (red), and when light (electromagnetic wave) is incident on each pixel, each pixel generates a color signal (electric signal) of the same color as the associated filter.

In the camera module 10 configured in this way, a reflection light from a subject is emitted out of the lighting hole 12, the lens 13, the lens 14, the infrared cut filter 17 and the center hole 16, and then is received by the imaging surface 19 of the imaging element 18, so as to take an image of the subject. In addition, the infrared cut filter 17 and the imaging element 18 of the components of the camera module 10 are constituent elements of an imaging element unit U.

The unique sensitivity of each pixel of the imaging surface 19 of the imaging element 18 is different depending on the wavelength of the electromagnetic wave, and an RGB combined relative sensitivity can be obtained by combining all the unique sensitivities of the pixels of the imaging surface 19.

The infrared cut filter 17 shows an extremely high transmittance (equal to or more than 90%) with respect to the electromagnetic wave of 400 nm to 650 nm (or around 650 nm) in wavelength by properly selecting the number, thickness and refractive index of each layer of the thin film, and its transmittance characteristics are set so that the transmittance gradually decreases as the wavelength lengthens with respect to the electromagnetic wave of wavelengths longer than 650 nm (or around 650 nm).

The infrared cut filter 17 having this function is placed immediately in front of the imaging surface 19 of the imaging element 18 and thereby a relative sensitivity which is an actual sensitivity of the imaging surface 19 is different from an RGB combined relative sensitivity. In other words, the relative sensitivity of the imaging surface 19 is almost the same as the RGB combined relative sensitivity, with respect to the electromagnetic wave of 400 nm to 650 nm in wavelength; however, it is lower than the RGB combined relative sensitivity, with respect to the electromagnetic wave of 650 nm to 900 nm in wavelength. In detail, as shown in the spectral characteristic graph of FIG. 2 where the wavelength of the electromagnetic wave is expressed on the transverse axis and the relative sensitivity is expressed on the longitudinal axis, a part corresponding to the wavelength of 650 nm to 850 nm tilts rightward nearly linearly, and a part corresponding to the wavelength of 850 nm to 900 nm has a slow gradient (a range shorter than 650 nm in wavelength and a range longer than 900 nm in wavelength are not shown). If describing the part corresponding to the wavelength of 650 nm to 900 nm in detail, the relative sensitivity of the imaging surface 19 corresponding to this wavelength range lies in an area A surrounded by a straight line connecting a first relative sensitivity P1 in a wavelength λ, of 650 nm (the first relative sensitivity is the maximum value. The following is the same.) to a second relative sensitivity P2 in a wavelength λ, of 650 nm (the second relative sensitivity is the minimum value. The following is the same.), a straight line connecting the P2 to a second relative sensitivity P4 in a wavelength λ, of 850 nm, a straight line connecting the P4 to a second relative sensitivity P6 in a wavelength λ, of 900 nm, a straight line connecting the P6 to a first relative sensitivity P5 in a wavelength λ, of 900 nm, a straight line connecting the P5 to a first relative sensitivity P3 in a wavelength λ, of 850 nm, and a straight line connecting the P3 to the first relative sensitivity P1. The relation between the respective wavelengths of 650 nm, 700 nm, 750 nm, 800 nm, 850 nm and 900 nm, and the relative sensitivity of the imaging surface 19 is given as the following table (the relative sensitivity is expressed by a central value and an allowable variation (±) with respect to the central value, in each wavelength).

| λ | relative sensitivity |
|---|---|
| (wavelength: unit of nm) | (a.u. = arbitrary unit) |
| 650 | 77 ± 10 |
| 700 | 62 ± 10 |
| 750 | 44 ± 7 |
| 800 | 26 ± 7 |
| 850 | 7 ± 5 |
| 900 | 5 ± 5 |

If the relative sensitivity of the imaging surface 19 is lower than the numerical value in this range, its sensitivity with respect to infrared light decreases, and thereby a subject image cannot be clearly taken by the imaging element 18 although using infrared light (infrared light included in the illumination light of a car or the illumination of a building, or the like) in an environment where the amount of visible light is not sufficient like nighttime. In contrast, if the relative sensitivity is higher than the numerical value in this range, the imaging element 18 is much influenced by infrared light (infrared light included in the sunlight, or the like), and thereby a color reproducibility of the taken image is degraded although the imaging is performed in an environment where the amount of visible light is sufficient like daytime. For example, when an electromagnetic wave of about 650 nm in wavelength is cut as much as roughly 50% and most of infrared light in wavelength longer than 700 nm is cut like the infrared cut filter in the related art, a clear subject image cannot be taken by the imaging element 18 although using infrared light in an environment where the amount of visible light is not sufficient like nighttime.

On the other hand, in this embodiment, the relative sensitivity of the imaging surface 19 satisfies the above-described condition with respect to the wavelength of 650 nm to 900 nm in consideration of the transmittance characteristics of the infrared cut filter 17, and thus a subject image can be clearly taken in both nighttime and daytime regardless of placing the infrared cut filter 17 immediately in front of the imaging element 18. In addition, it is not necessary to move the infrared cut filter 17 with respect to the imaging element 18, and thereby the structure of the camera module 10 is not complex and manufacturing costs are not high.

The infrared cut filter 17 is not the lamination type (reflection type) as described above, but may be a so-called absorption type containing phosphorus pentoxide or aluminum trioxide or the like. A design method for giving desired transmittance characteristics to the infrared cut filter 17 by properly adjusting a kind and a containing amount, etc. of a contained matter has been known in the art as well.

In the infrared cut filter 17, the above-described thin film is not formed only on the one surface but may be formed on both surfaces. In addition, the anti-reflection coating of the infrared cut filter 17 is removed, and, instead thereof, the filter substrate of the infrared cut filter 17 and the cover glass (not shown) of the imaging element 18 may be attached to each other by an optical adhesive which is suitable to the refractive index of the filter substrate and the refractive index of the cover glass. Further, the filter substrate and the anti-reflection coating is removed from the infrared cut filter 17, and, instead thereof, the thin film of the infrared cut filter 17 may be implemented on the surface of the cover glass of the imaging element 18.

The camera module 10 may be provided with an infrared light source (for example, an infrared LED) emitting infrared light of 800 nm to 900 nm in wavelength, and infrared light may be irradiated from the infrared light source to a subject when the amount of visible light is not sufficient like nighttime.

The embodiments of the invention are successively described.

### Embodiment 1

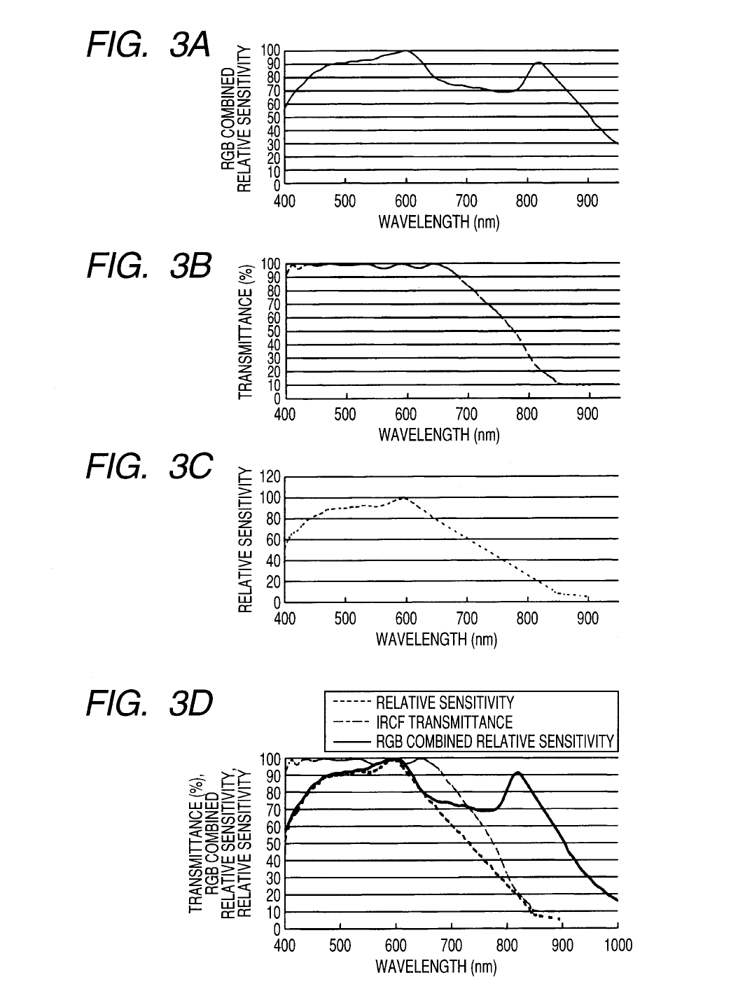

The transmittance characteristics of the infrared cut filter 17 and the RGB combined relative sensitivities of the imaging element 18 according to the embodiment 1 are shown in the graphs of FIGS. 3A to 3D.

The imaging surface 19 of the imaging element 18 shows the highest RGB combined relative sensitivity with respect to an electromagnetic wave of a wavelength slightly longer than 600 nm, and its RGB combined relative sensitivity gradually decreases as a wavelength lengthens than this wavelength. The RGB combined relative sensitivity increases again with respect to an electromagnetic wave of about 830 nm in wavelength, and the RGB combined relative sensitivity decreases again as a wavelength lengthens than 830 nm.

However, the relative sensitivity of the imaging surface 19 when the infrared cut filter 17 is placed immediately in front of the imaging element 18 is different from the RGB combined relative sensitivity. That is to say, the relative sensitivity is almost the same as the RGB combined relative sensitivity with respect to a wavelength (visible light) of 400 nm to 650 nm; however, a part corresponding to a wavelength of 650 nm to 900 nm goes downward nearly linearly (although not shown, a transmittance with respect to wavelengths longer than 900 nm is 0.).

As above, the imaging surface 19 in the embodiment 1 shows a high relative sensitivity with respect to the electromagnetic wave (visible light) of 400 nm to 600 nm in wavelength, and thereby a subject can be clearly imaged in an environment where the amount of visible light is sufficient like daytime. Further, a subject can be clearly imaged by using infrared light in an environment where the amount of visible light is not sufficient like nighttime.

### Embodiment 2

The embodiment 2 will be described.

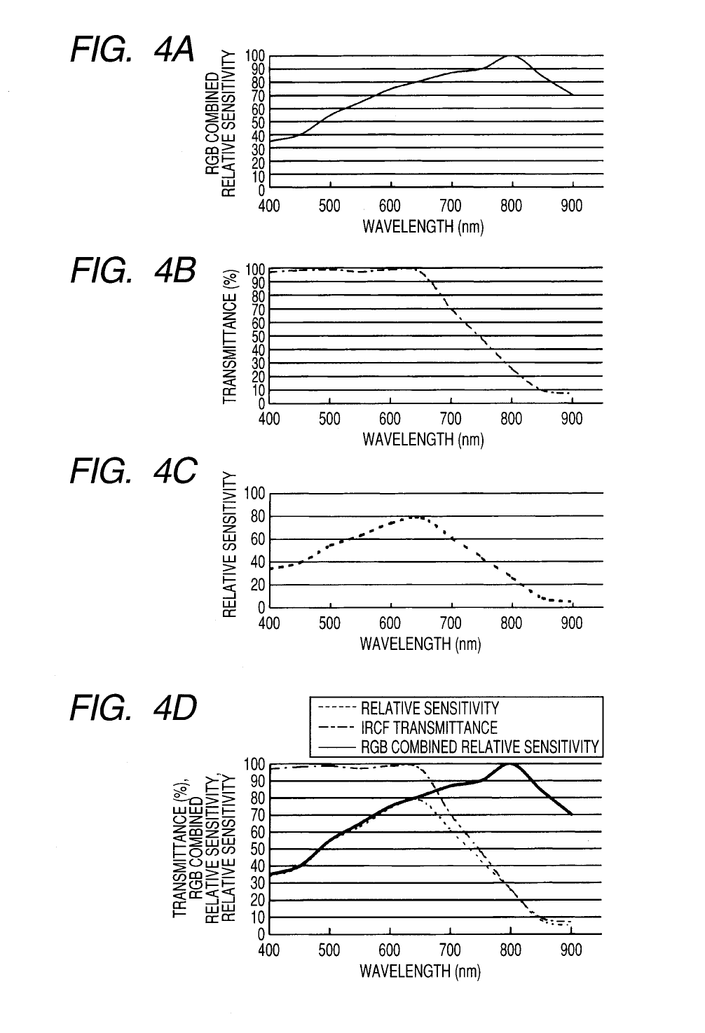

The transmittance characteristics of the infrared cut filter 17 and the RGB combined relative sensitivities of the imaging element 18 according to the embodiment 2 are shown in graphs of FIGS. 4A-D.

The imaging surface 19 of the imaging element 18 shows the highest RGB combined relative sensitivity with respect to a wavelength of about 800 nm, and its RGB combined relative sensitivity gradually decreases as the wavelength becomes longer than this wavelength.

On the other hand, the relative sensitivity of the imaging surface 19 when the infrared cut filter 17 is placed immediately in front of the imaging element 18 is almost the same as the RGB combined relative sensitivity with respect to a wavelength (visible light) of 400 nm to 650 nm; however, a part corresponding to a wavelength of 650 nm to 900 nm goes downward nearly linearly (although not shown, a transmittance with respect to wavelengths longer than 900 nm is 0.).

As above, the imaging surface 19 in the embodiment 2 shows a high relative sensitivity with respect to the electromagnetic wave (visible light) of 400 nm to 600 nm in wavelength, and thereby a subject can be clearly imaged in an environment where the amount of visible light is sufficient like daytime. Further, a subject can be clearly imaged by using infrared light in an environment where the amount of visible light is not sufficient like nighttime.

It should be understood by those skilled in the art that various modifications, combinations, sub-combinations and alterations may occur depending on design requirements and other factors insofar as they are within the scope of the appended claims of the equivalents thereof.

What is claimed is:

1. An imaging element unit comprising:
an imaging element configured to include an imaging surface having a plurality of R pixels, G pixels and B pixels; and
an infrared cut filter configured to be placed in a position immediately in front of the imaging surface,
wherein the transmittance characteristics of the infrared cut filter are determined so that an RGB combined relative sensitivity which is a combined value of unique sensitivities of the R pixels, the G pixels and the B pixels and a relative sensitivity of the imaging surface determined by the transmittance characteristics of the infrared cut filter show each of the following sensitivities with respect to each of the following wavelengths longer than 600 nm.

| λ | |
|---|---|
| (wavelength: unit of nm) | relative sensitivity |
| 650 | 77 ± 10 |
| 700 | 62 ± 10 |
| 750 | 44 ± 7 |
| 800 | 26 ± 7 |
| 850 | 7 ± 5 |
| 900 | 5 ± 5 |

2. An imaging element unit comprising:
an imaging element configured to include an imaging surface having a plurality of R pixels, G pixels and B pixels; and
an infrared cut filter configured to be placed in a position immediately in front of the imaging surface,
wherein the transmittance characteristics of the infrared cut filter are determined so that, in an RGB combined relative sensitivity which is a combined value of unique sensitivities of the R pixels, the G pixels and the B pixels and a relative sensitivity of the imaging surface determined by the transmittance characteristics of the infrared cut filter, the relative sensitivity with respect to each wavelength of 650 nm to 900 nm lies in an area surrounded by straight lines connecting the following P1 to the P2, the P2 to the P4, the P4 to the P6, the P6 to the P5, the P5 to the P3, and the P3 to the P1, respectively, when a wavelength of an electromagnetic wave is expressed on a transverse axis and the relative sensitivity with respect to each wavelength is expressed on a longitudinal axis.
A first relative sensitivity in a wavelength λ, of 650 nm P1: 87
A second relative sensitivity in a wavelength λ, of 650 nm P2: 67
A first relative sensitivity in a wavelength λ, of 850 nm P3: 12
A second relative sensitivity in a wavelength λ, of 850 nm P4: 2
A first relative sensitivity in a wavelength λ, of 900 nm P5: 10
A second relative sensitivity in a wavelength λ, of 900 nm P6: 0.

3. The imaging element unit according to claim 1, wherein the imaging element unit is embedded in a car-mounted camera.
